(19) United States
(12) Patent Application Publication
(10) Pub. No.: US 2009/0084436 A1
(43) Pub. Date: Apr. 2, 2009

(54) Effective organic solar cells based on triplet materials

(75) Inventors: Yang Yang, Los Angeles, CA (US); Yan Shao, Los Angeles, CA (US)

Correspondence Address: VENABLE LLP, P.O. BOX 34385, WASHINGTON, DC, 20043-9998, US

(73) Assignee: The Regents of the University of California, Oakland, CA (US)

(21) Appl. No.: 11/921,236

(22) PCT Filed: Jun. 1, 2006
(86) PCT No.: PCT/US2006/021155

§ 371 Date: Nov. 29, 2007

Related U.S. Application Data
(60) Provisional application No. 60/686,741, filed on Jun. 2, 2005.

(51) Int. Cl. H01L 31/00; B05D 5/12

(52) U.S. Cl. 136/256; 427/74

(57) ABSTRACT

A photovoltaic device has a first electrode, a second electrode spaced apart from the first electrode, and a layer of light responsive material disposed between the first electrode and the second electrode. The layer of light responsive material includes a material that has a triplet exciton state which can be excited by incident electromagnetic radiation to provide collectable free charged particles at one of the first and second electrodes.

### CROSS-REFERENCE OF RELATED APPLICATION

This application claims priority to U.S. Provisional Application No. 60/686,741 filed Jun. 2, 2005, the entire contents of which are hereby incorporated by reference.

The U.S. Government has a paid-up license in this invention and the right in limited circumstances to require the patent owner to license others on reasonable terms as provided for by the terms of ONR Grant No. N00014-04-1-0434.

### BACKGROUND

1. Field of Invention

This application relates to solar cells, and more particularly to organic solar cells based on triplet materials.

2. Discussion of Related Art

The contents of all references, including articles, published patent applications and patents referred to herein are hereby incorporated by reference.

Solar cells, also known as photovoltaic (PV) cells or devices, generate electrical power from incident light. The term “light” is used broadly herein to refer to electromagnetic radiation which may include visible, ultraviolet and infrared light. Traditionally, PV cells have been constructed of a number of inorganic semiconductors, e.g., crystalline, polycrystalline and amorphous silicon, gallium arsenide, cadmium telluride and others. More recently, PV cells have been constructed using organic materials.

Solar cells are characterized by the efficiency with which they can convert incident solar power to useful electric power. Devices utilizing crystalline or amorphous silicon dominate commercial applications, and some have achieved efficiencies of 23% or greater. However, efficient crystalline-based devices, especially of large surface area, are difficult and expensive to produce due to the problems inherent in producing large crystals without significant efficiency-degrading defects. On the other hand, high efficiency amorphous silicon devices still suffer from problems with stability. Present commercially available amorphous silicon cells have stabilized efficiencies between 4 and 8%. More recent efforts have focused on the use of organic photovoltaic cells to achieve acceptable photovoltaic conversion efficiencies with economical production costs as well as other possible advantageous properties.

PV devices produce photo-generated voltages when they are connected across a load and are irradiated by light. When irradiated without any external electronic load, a PV device generates its maximum possible voltage, V open-circuit, or V_{OC}. If a PV device is irradiated with its electrical contacts shorted, a maximum short-circuit current, or I_{SC}, is produced. When actually used to generate power, a PV device is connected to a finite resistive load in which the power output is given by the product of the current and voltage, I×V. The maximum total power generated by a PV device is inherently incapable of exceeding the product I_{SC}×V_{OC}. When the load value is optimized for maximum power extraction, the current and voltage have values, Iₘₐₓ and Vₘₐₓ, respectively. A figure of merit for solar cells is the fill factor, ff, defined as:

$$ff = \frac{{I}_{max} {V}_{max}}{{I}_{SC} {V}_{OC}}$$

where ff is always less than 1, as I_{SC} and V_{OC} are never achieved simultaneously in actual use. Nonetheless, as ff approaches 1, the device is more efficient.

When electromagnetic radiation of an appropriate energy is incident upon a semiconductive organic material, for example, an organic molecular crystal (OMC) material, or a polymer, a photon can be absorbed to produce an excited molecular state. This energy absorption is associated with the promotion of an electron from a bound state in the highest occupied molecular orbital (HOMO) to the lowest unoccupied molecular orbital (LUMO), or equivalently, the promotion of a hole from the LUMO to the HOMO. In organic thin-film photoconductors, the generated excited state is believed to be an exciton, i.e., an electron-hole pair in a bound state which is transported as a quasi-particle. The excitons can have an appreciable life-time before recombination. To produce a photocurrent the electron-hole pair must become separated, for example at a donor-acceptor interface between two dissimilar contacting organic thin films. The interface of these two materials is called a photovoltaic heterojunction If the charges do not separate, they can recombine with each other (known as quenching) either radiatively, by the emission of light of a lower energy than the incident light, or non-radiatively, by the production of heat. Either of these outcomes is undesirable in a PV device.

In traditional semiconductor theory, materials for forming PV heterojunctions have been denoted as generally being of either n (donor) type or p (acceptor) type. Here n-type denotes that the majority carrier type is the electron. This could be viewed as the material having many electrons in relatively free energy states. The p-type denotes that the majority carrier type is the hole. Such material has many holes in relatively free energy states. The type of the background majority carrier concentration depends primarily on unintentional doping by defects or impurities. The type and concentration of impurities determine the value of the Fermi energy, or level, within the gap between the highest occupied molecular orbital (HOMO) and the lowest unoccupied molecular orbital (LUMO), called the HOMO-LUMO gap. The Fermi energy characterizes the statistical occupation of molecular quantum energy states denoted by the value of energy for which the probability of occupation is equal to ½. A Fermi energy near the LUMO energy indicates that electrons are the predominant carrier. A Fermi energy near the HOMO energy indicates that holes are the predominant carrier. Accordingly, the Fermi energy is a primary characterizing property of traditional semiconductors and the PV heterojunction has traditionally been the p-n interface.

A significant property in organic semiconductors is carrier mobility. Mobility measures the ease with which a charge carrier can move through a conducting material in response to an electric field. As opposed to free carrier concentrations, carrier mobility is determined in large part by intrinsic properties of the organic material such as crystal symmetry and periodicity. Appropriate symmetry and periodicity can produce higher quantum wavefunction overlap of HOMO levels producing higher hole mobility, or similarly, higher overlap of LUMO levels to produce higher electron mobility. Moreover, the donor or acceptor nature of an organic semiconductor may be at odds with the higher carrier mobility. The result is that device configuration predictions from donor/acceptor criteria may not be borne out by actual device performance. Due to these electronic properties of organic materials, the nomenclature of “hole-transporting-layer” (HTL) or “electron-transporting-layer” (ETL) is often used rather than designating them as “p-type” or “acceptor-type” and “n-type” or “donor-type”. In this designation scheme, an ETL will be preferentially electron conducting and an HTL will be preferentially hole transporting.

Organic PV cells have many potential advantages when compared to traditional silicon-based devices. Organic PV cells are light weight, economical in the materials used, and can be deposited on low cost substrates, such as flexible plastic foils. However, organic PV devices typically have relatively low quantum yield (the ratio of photons absorbed to carrier pairs generated, or electromagnetic radiation to electricity conversion efficiency), being on the order of 1% or less. This is, in part, thought to be due to the second order nature of the intrinsic photoconductive process. That is, carrier generation requires exciton generation, diffusion and ionization. However, the diffusion length (L_{D}) of an exciton is typically much less than the optical absorption length, requiring a trade off between using a thick, and therefore resistive, cell with multiple or highly folded interfaces, or a thin cell with a low optical absorption efficiency. There is thus a need for improved organic photovoltaic devices.

### SUMMARY

Further objectives and advantages will become apparent from a consideration of the description, drawings, and examples.

Accordingly, a photovoltaic device according to an embodiment of this invention has a first electrode, a second electrode spaced apart from the first electrode, and a layer of light responsive material disposed between the first electrode and the second electrode. The layer of light responsive material includes a material that has a triplet exciton state which can be excited by incident electromagnetic radiation to provide collectable free charged particles at one of the first and second electrodes.

A method of generating electric power according to an embodiment of this invention includes illuminating a layer of light responsive material with electromagnetic radiation to cause triplet excitons to form in the layer of light responsive material, allowing the excitons to migrate to an interface region of the donor and acceptor materials to dissociate electrons from corresponding holes of the excitons, and collecting at least some of the dissociated electrons at an electrode to be available for providing electrical power.

A method of producing a photovoltaic device according to an embodiment of this invention includes providing a substrate, forming a first electrode on the substrate, selecting a light responsive material that comprises a triplet material having a relatively stable triplet exciton state, forming a layer of the light responsive material on the first electrode, and forming a second electrode in electrically conducting contact with the layer of light responsive material The triplet material has a triplet exciton state suitable to be excited by incident electromagnetic radiation to produce electrical power.

### BRIEF DESCRIPTION OF THE DRAWINGS

The invention may be better understood by reading the following detailed description with reference to the accompanying figures in which:

FIG. 1 shows examples of some triplet materials available for organic photovoltaic devices;

FIG. 2 is a schematic illustration of a photovoltaic device according to an embodiment of the current invention;

FIG. 3 shows the configuration of the device structure, chemical structures for organic materials, and schematic energy level diagram for an example of a PV device according to an embodiment of the current invention;

FIG. 4 shows dark current (dash dot line) and photocurrent (solid line) density-voltage curves of the photovoltaic device with structure as ITO/PEDOT/PtOEP(300 Å)/C₆₀(300 Å)/BCP(80 Å)/Al(1000 Å) according to an example for an embodiment of the current invention;

FIG. 5 shows dark current (dash dot line) and photocurrent (solid line) density-voltage curves of the photovoltaic device with structure as ITO/PEDOT/PtOEP(300 Å)/C₆₀(300 Å)/BCP(80 Å)/Al(1000 Å) after 60 minutes heat treatment at 100° C. under nitrogen environment in glove box according to an example for an embodiment according to the current invention; and

FIG. 6 shows UV-VIS spectra for 30 nm neat PtOEP film and 30 nm PtOEP/30 nm C₆₀ heterojunction film according to an example for an embodiment of the current invention.

### DETAILED DESCRIPTION

In describing embodiments of the present invention illustrated in the drawings, specific terminology is employed for the sake of clarity. However, the invention is not intended to be limited to the specific terminology so selected. It is to be understood that each specific element includes all technical equivalents which operate in a similar manner to accomplish a similar purpose.

Many organic materials have been utilized to make organic photovoltaic devices in heterojunction and bulkjunction structures. In order to obtain high power conversion efficiencies, high mobility materials with appropriate bandgaps are desired to enhance carrier transport abilities and improve light absorption. From another point of view, it is very important to select appropriate materials with extended exciton diffusion length for organic photovoltaic heterojunctions. Much effort has been made during the past two decades in the search for organic photovoltaic materials and related device architectures since the donor-acceptor heterojunction interface was demonstrated as an effective exciton dissociation structure. (See C. W. Tang, Appl. Phys. Lett. 1986, 48, 183; G. Yu, J. Gao, J. C. Hummelen, F. Wudl, A. J. Heeger, Science, 1995, 270, 1789; and P. Peumans, A. Yakimov, S. R. Forrest, J. Appl. Phys. 2003, 93, 3693.) The effective organic photovoltaic materials include small molecules and polymers with relatively high conductivity or mobility. The power conversion efficiencies of organic photovoltaic devices are dependent on three key processes: light absorption, exciton dissociation, and charge collection. (See P. Peumans, S. Uchida, S. R. Forrest, Nature, 2003, 425, 158.) The external quantum efficiency can be estimated as ηₜₒₜₐₗ=η_{Absorption}η_{dissociation}η_{collection}, where ηₜₒₜₐₗ stands for total external quantum efficiency, η_{Absorption} for light absorption, η_{dissociation} for exciton dissociation, and η_{collection} for electrode collection.

There are two general types of organic photovoltaic structures: heterojunctions and bulkjunctions (or so-called interpenetration network structures for the case of polymer blends), which provide respective advantages. Heterojunction devices often have multi-layer structures and are formed by layer-by-layer material deposition. Bulkjunction PV devices can be fabricated by blending or codeposition methods. (See H. J. Snaith, N. C. Greenham, R. H. Friend, Adv. Mater. 2004, 16, 1640.) The interpenetration network PV devices have proved to be very efficient exciton dissociation systems, especially for recently reported highly efficient polymer-based devices. The exciton and charge transport properties can be altered after formation of bulkjunctions, since phase separation and film morphology can play more important roles than respective pure materials, so that the mixtures might be considered as whole systems with their properties to be determined after fabrication.

On the other hand, heterojunctions are relatively simple systems and the transport properties, crystalline order, and film morphology could be preserved relatively well. Therefore, materials could be characterized independently before device fabrication and different components could be substituted conveniently. Many valuable parameters can be determined experimentally in heterojunction systems. (P. Peumans, A. Yakimov, S. R. Forrest, J. Appl. Phys. 2003, 93, 3693.) In this case, heterojunctions are well-suited for investigating new materials and for theoretical research regarding photovoltaic devices. To gain high power conversion efficiency, firstly, organic layers should be thick enough to ensure high light absorption efficiency, although, many organic photovoltaic materials possess better light absorption abilities compared with the inorganic counterparts with similar bandgaps and thicknesses. Currently, the organic layers used in organic photovoltaic devices are often insufficiently thick due to poor exciton mobility or carrier transport of organic materials. In other words, their exciton diffusion lengths (L_{D}) cannot match the respective optical absorption lengths. (P. Peumans, A. Yakimov, S. R. Forrest, J. Appl. Phys. 2003, 93, 3693.) The exciton diffusion length is dependent on two factors: exciton mobility and lifetime. In order to improve exciton diffusion length we can adopt high mobility organics, with which many high performance photovoltaic devices have been demonstrated, (See, for example, G. Yu, J. Gao, J. C. Hummelen, F. Wudl, A. J. Heeger, Science, 1995, 270, 1789) or on the other hand, we can introduce materials with long exciton lifetime. In this case, triplet materials can provide excellent candidates since they often possess much longer exciton lifetimes compared with singlet lifetimes. Long lifetime is also good for the charge collection process following exciton dissociation, especially for electron acceptor materials, since the situations are similar. Fullerene (C₆₀) is one of the best organic acceptor materials for organic photovoltaic structure with excellent exciton mobility, relatively stable triplet state, and therefore, relatively extended exciton diffusion length, which has been reported to be as long as 400 Å. (P. Peumans, A. Yakimov, S. R. Forrest, J. Appl. Phys. 2003, 93, 3693.) Combined with its high electron affinity (EA) and good photon absorption in visible region, C₆₀ and its derivatives have received much attention and been adopted extensively in a lot of organic solar cells. However, as an acceptor material, it is doubtful that the use of C₆₀ alone as a triplet material in this way can provide significantly enhanced charge collection through production of triplet excitons.

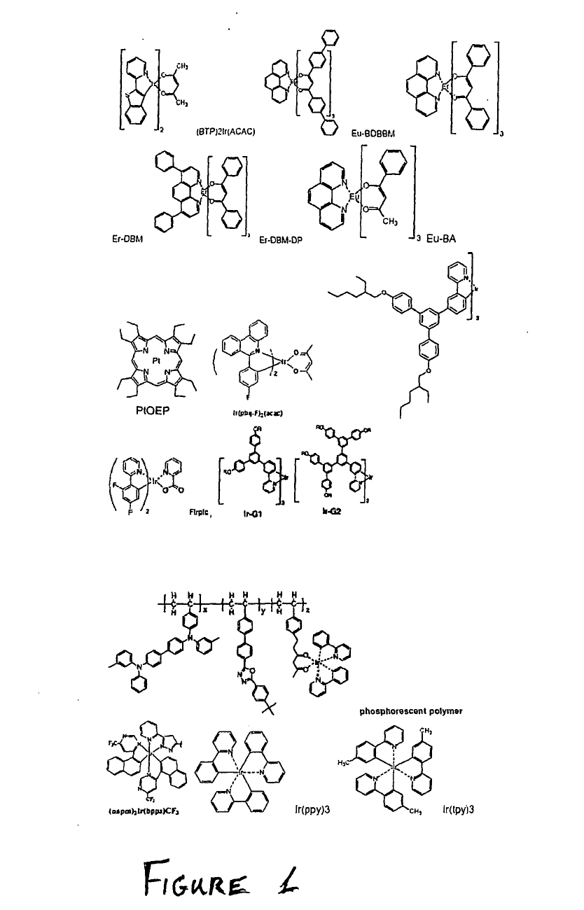

According to an aspect of the current invention, a new type of organic photovoltaic devices is provided by utilizing materials with long exciton lifetime. In particular, organic triplet materials provide good candidates for this kind of long exciton lifetime materials. The triplet materials can include small-molecule triplet materials and polymer triplet materials. Solar cells according to the current invention can include bulkjunction as well as heterojunction PV devices, which can be prepared, for example, by solution processes or thermal depositions and codepositions. Typical exciton lifetimes for fluorescent organic materials are on the order of ˜10⁻⁹ s (S. Blumstengel, F. Meinardi, R. Tubino, M. Gurioli, M. Jandke, P. Strohriegl, J. Chem. Phys. 2001, 115, 3249) while typical exciton lifetimes for phosphorescent organic materials are on the order of ˜10⁻⁶ s. (M. A. Baldo, D. F. O'Brien, Y. You, A. Shoustikov, S. Sibley, M. E. Thompson, S. R. Forrest, Nature, 1998, 395, 151; S. Blumstengel, F. Meinardi, R. Tubino, M. Gurioli, M. Jandke, P. Strohriegl, J. Chem. Phys. 2001, 115, 3249.) This three-order difference can be utilized to extend exciton diffusion length greatly, if proper triplet materials are available for PV devices. The processes occurring in photovoltaic devices are the reverse of the ones in OLEDs, therefore the criteria of selecting materials should be different. However, triplet organic materials designed for photovoltaic devices have not emerged extensively compared to triplet materials for OLEDs and the many phosphorescent materials used in OLEDs are now available commercially. It is convenient to select some triplet materials from OLED materials and use them in demonstrating photovoltaic devices. However, the general concepts of the invention are not limited to only such materials. The first consideration is the visible light absorption ability, which is often the weak point for many triplet materials due to their relatively high ionization potential (IP) of the first excited single state. The second consideration is appropriate energy levels to form efficient heterojunctions with proper energy-level offsets. In addition, similar approaches can also be applied to polymer versions of solar cells, by either blending of triplet molecules (organic or inorganic) with a polymer host as the active materials. Alternatively, heavy atomic mass metal nano-particles or other means which can help to convert to a triplet energy level exciton can be utilized as materials for the solar cells. In addition, polymers with triplet energy levels can be used as the host according to some embodiments of this invention. A general concept is to extend the lifetime of the carriers to have a longer diffusion length by appropriately selecting the material. There are a lot of triplet materials currently available, including small-molecule and polymer type triplet materials. FIG. 1 shows some examples of some currently available triplet materials. These are shown as examples. These are examples involving transition metals. However, this invention is not limited to only triplet materials involving transition metals. Triplet materials involving non-transition metals may also provide appropriate triplet materials for certain applications of this invention. Furthermore, the general concepts of this invention are not limited to only the listed materials and are not limited to only currently available or currently known triplet materials.

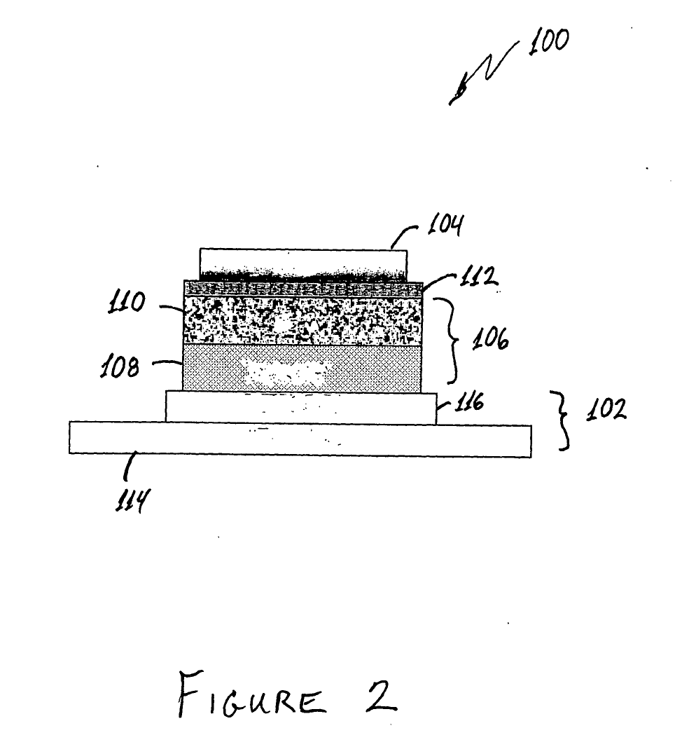

FIG. 2 illustrates a PV device 100 according to an embodiment of the current invention. The PV device 100 has a first electrode 102, a second electrode 104 and a layer of light responsive material 106 disposed between the first electrode 102 and the second electrode 104. The layer of light responsive material 106 comprises a material having a triplet exciton state which can be excited by incident electromagnetic radiation to provide collectable free charged particles at one of the first electrode 102 and the second electrode 104. General concepts of the invention are not limited to only a single photon exciting a single exciton. A single photon may lead to more than one exciton and/or more than one photon may excite one or more excitons. The layer of light responsive material 106 may include two, three or more types of triplet materials in particular embodiments of the invention. General concepts of this invention are not limited to the particular number of triplet materials. Furthermore, the layer of light responsive material 106 may be a bulkjunction (interpenetration network) structure, a heterojunction structure, or a combination of one or more bulkjunction and/or one or more heterojunction structures. For example, the layer of light responsive material 106 may have a heterojunction structure with a donor layer 108 and an acceptor layer 110. Each of the donor layer 108 and acceptor layer 110 may be made from a different triplet material selected in accordance with the criteria noted above. In addition, one may select materials for the donor layer 108 and acceptor layer 110 such that the difference in energy levels corresponds to the dissociation energy of triplet excitons of the donor material, i.e., the energy required to dissociate an electron from a hole to provide free charge carriers.

The PV device 100 may also include a hole/exciton blocking layer 112 between the layer of light responsive material 106 and the first electrode 102. One may select a material for the hole/exciton blocking layer 112 from available materials according to the desired application. The current invention is not limited to specific materials of the hole/exciton blocking layer 112. The first electrode 102 may have a simple structure or may comprises a complex structure, such as having more than one layer of material. For example, the first electrode 102 may include ITO on a substrate 114. The substrate may be a substrate that is substantially transparent to electromagnetic radiation at the operating wavelengths of the PV device. For example, the substrate may be glass in some embodiments. However, the invention is not limited to a particular material for the substrate. The first electrode 102 may include other layers 116, for example PEDOT has been found to be suitable for some particular embodiments of this invention. The second electrode 104 may also be a simple structure or a complex structure. For example, it may be a conductive metal or alloy according to some embodiments of this invention.

The following provide a couple of specific examples of PV cells that were constructed according to embodiments of the current invention. The general concepts of this invention are not limited to these specific examples.

### EXAMPLE 1

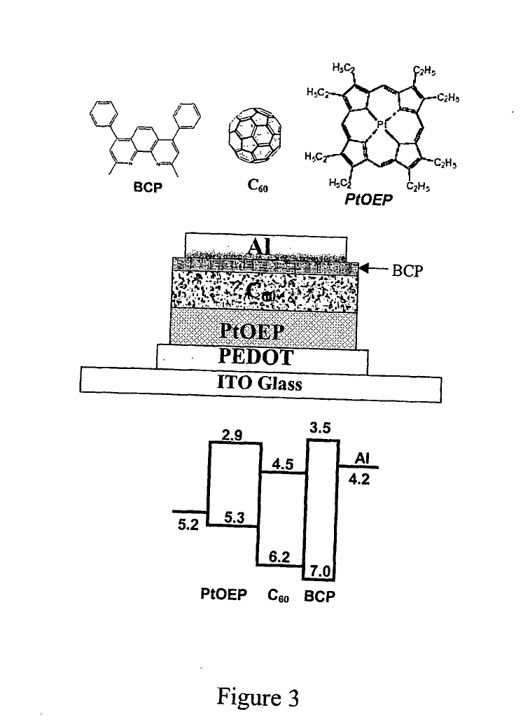

PtOEP was selected for the electron donor material and C₆₀ was used as the electron acceptor material in this example according to the current invention. In particular, 2,3,7,8,12,13,17,18-octaethyl-21H,23H-porphine platinum (II) (PtOEP) is one example of a triplet donor material that was found to be suitable for organic photovoltaic devices according to an embodiment of the current invention. Both of these triplet materials have strong triplet electron states, excellent thermal stabilities, and good abilities to form thin films. Unlike triplet materials adopted in phosphorescent OLEDs, where they are often used as dopants, neat PtOEP thin films were employed for photovoltaic heterojunctions in this embodiment because exciton diffusion ability and carrier mobility would be affected by energy trapping structures of doping thin films. 2,9-dimethyl-4,7-diphenyl-1,10-phenanthroline (BCP) served as the hole/exciton blocker between the C₆₀ layer and the Al electrode. Indium-tin-oxide (ITO) glass coated with poly(3,4-ethylenedioxythiophene)poly(styrene) (PEDOT-PSS) film was adopted as a substrate. FIG. 3 shows the configuration of the device structure, chemical structures for organic materials, and schematic energy level diagram for this example of the current invention. The energy level values of PtOEP are taken from the literature. The energy-level offset for heterojunction between PtOEP and C₆₀ is nearly perfect for exciton dissociation and the electron affinity of PtOEP should match the ITO/PEDOT very well for hole transport.

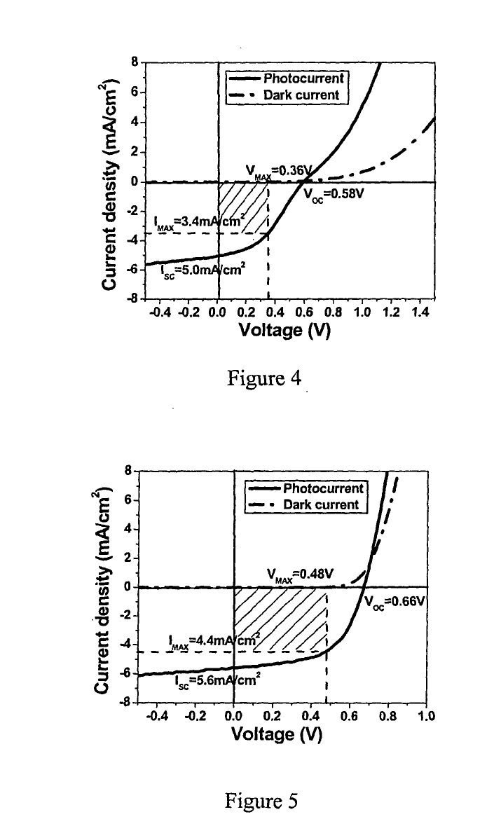

The detailed photovoltaic device structure and thickness for each organic functional layer in this example are ITO/PEDOT/PtOEP(300 Å)/C₆₀(300 Å)/BCP(80 Å)/Al(1000 Å). The series resistance can be calculated from the nearly linear part of the dark current and it was found to be about 43 Ωcm² for the devices which had 300 Å PtOEP and 300 Å C₆₀. In our experiment, when the thicknesses of the PtOEP layer were greater than 400 Å the photovoltaic devices showed lower power conversion efficiencies. This observation suggests that the mobility of PtOEP may be smaller than desired for some applications and higher mobility materials can result in better device performance. FIG. 4 shows the device performance under 100 mW/cm² AM1.5G illumination. The open circuit voltage (V_{OC}) is 0.58V and the short circuit current density (I_{SC}) is 5 mA/cm2. FIG. 4 also shows the maximum power output by the shaded rectangular area with V_{MAX} of 0.36V and I_{MAX} of 3.4 mA/cm², which leads to a fill factor of 0.42 and a power conversion efficiency of 1.2%. Notice that this device has a relatively high resistance and poor fill factor and the conductivity of the photocurrent curve is clearly higher than the one of the dark current curve, which can be thought of as the photoconductivity behavior of the device.

FIG. 5 shows performance of the device after 60 minutes of heat treatment at 100° C. under a nitrogen environment in a glove box. The results are much better than those without heat treatment. The series resistance was calculated to be about 5.3 Ωcm², which was much smaller than that of the same devices without heat treatment. All three of the important characteristics, open circuit voltage, short circuit current density, and fill factor, were improved. Here, the V_{OC} is 0.66V and the I_{SC} is 5.6 mA/cm². Additionally, FIG. 5 shows the maximum power output with V_{MAX} of 0.48V and I_{MAX} of 4.4 mA/cm², which gives a fill factor of 0.57 and a power conversion efficiency of 2.1%. The conductivities of both photocurrent status and dark current were enhanced greatly, which might be ascribed to crystallization of PtOEP caused by heat treatment and consequent mobility enhancement. This kind of performance enhancement has been reported in several different photovoltaic devices. (See P. Peumans. S. Uchida, S. R. Forrest, Nature, 2003, 425, 158.)

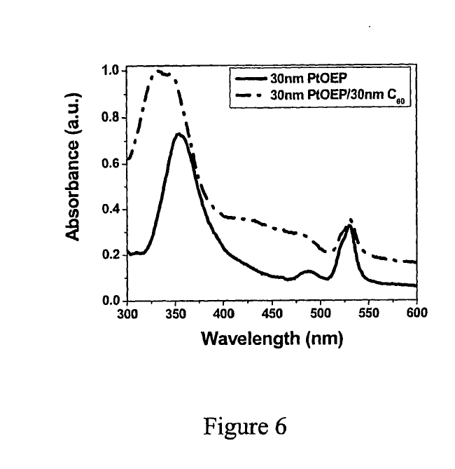

FIG. 6 shows the UV-VIS spectra for 30 nm neat PtOEP film and 30 nm PtOEP/30 nm C₆₀ heterojunction film. The absorbance of PtOEP at long wavelength provides essential complementarity of the total heterojunction absorption. The contribution of PtOEP for photon absorption is almost comparable to that of C₆₀ since the thicknesses of their layers in the photovoltaic devices are equal, while currently the layer of donor materials used in organic photovoltaic devices often has thinner thickness compared to that of typical acceptor materials like C₆₀. (P. Peumans, A. Yakimov, S. R. Forrest, J. Appl. Phys. 2003, 93, 3693.) Therefore, the absorption abilities of our heterojunction have been enhanced by using relatively thick layers of the donor materials, nevertheless, the absorbed photons are still less than that of some highly efficient bulkjunction devices with the same active area, for example blending of poly 3-hexylthiophene (P3HT) and methanofullerene [6,6]-phenyl C₆₁ butyric acid methyl ester (PCBM).

The organic photovoltaic devices were fabricated on patterned ITO-coated glass substrates, which had been cleaned by successive ultrasonic treatments in acetone and isopropyl alcohol. The ITO glass was then subjected to UV-ozone treatment. A thin layer of PEDOT-PSS film was spin-coated onto the ITO glass with a speed of 4000 rpm for 1 minute and then baked at 15° C. for 50 minutes in ambient conditions. The fabrication process was carried out under a base pressure of ˜7×10⁻⁷ Torr and the deposition rates for PtOEP, C₆₀, BCP, and Al were ˜0.1 Å/s, ˜0.1 Å/s, ˜0.8 Å/s and ˜7 Å/s, respectively. The organic materials used in the device fabrication were used as received without further purification. An Al cathode was evaporated through a shadow mask with an active area of approximately 0.12 cm². All of the electrical measurements were performed under a nitrogen atmosphere in a glove box at room temperature. The current-voltage (I-V) characteristics were recorded by a computer controlled Keithley 2400 source-measure unit (SMU). The photocurrent was measured under AM 1.5 solar illumination at 100 mW/cm² (1 sun) supplied by a Thermal Oriel 150W solar simulator and light intensity was monitored by a calibrated silicon photodiode for a 1.5 AM spectrum. The absorption spectra were measured on a Varian Cary 50 UV-visible spectrophotometer.

### EXAMPLE 2

For an example of a polymer solar cell, we use commercially available poly(3-hexylthiophnene) (P3HT). The device structure is a sandwich structure consisting of an anode (ITO/PEDOT) and cathode (Ca/Al) having a polymer blend of P3HT and PCBM in between. The P3HT blend is spin-casted at a thickness of about 200 nm. The purchased P3HT has a significant amount of heavy metal nano-particles, originally from the catalyst during the synthesis, and the solar cells show an efficiency of about 4.5%. After purification, the heavy metal nano particles have been removed, and the devices show much lower efficiency, around 2% of conversion efficiency. The heavy metal particles can be metals which assist the formation of triplet excitons. It is believed that metal particles can be replaced by organic molecules shown as examples in FIG. 1.

Effective organic photovoltaic devices based on typical triplet material PtOEP have been demonstrated in an example of an embodiment of this invention. Relatively high performance and 2.1% power conversion efficiency were obtained in this example according to the current invention. By introducing appropriate organic materials with long exciton lifetime according to the current invention, one may be able to improve photovoltaic performance. With the help of purposely-designed triplet materials for photovoltaic devices, organic photovoltaic devices based on triplet materials are expected to provide additional improvements according to the current invention. In addition, one may also adjust the device structure to match the material property such that the device performance can be maximized according to concepts of this invention. Proper electron and hole conduction layers or interface modification layers may also be used to boost device performance according to some aspects of the current invention.

The embodiments illustrated and discussed in this specification are intended only to teach those skilled in the art the best way known to the inventors to make and use the invention. Nothing in this specification should be considered as limiting the scope of the present invention. The above-described embodiments of the invention may be modified or varied, and elements added or omitted, without departing from the invention, as appreciated by those skilled in the art in light of the above teachings. It is therefore to be understood that, within the scope of the claims and their equivalents, the invention may be practiced otherwise than as specifically described.

We claim:

1. A photovoltaic device, comprising:
a first electrode;
a second electrode spaced apart from the first electrode; and
a layer of light responsive material disposed between the first electrode and the second electrode,
wherein said layer of light responsive material comprises a material having a triplet exciton state which can be excited by incident electromagnetic radiation to provide collectable free charged particles at one of said first and second electrodes.

2. A photovoltaic device according to claim 1, wherein said material having a triplet exciton state is a donor material.

3. A photovoltaic cell according to claim 2, wherein said layer of light responsive material comprises a second material having a triplet exciton state which can be excited by incident electromagnetic radiation.

4. A photovoltaic cell according to claim 3, wherein said second material having a triplet exciton state is an acceptor material.

5. A photovoltaic device according to claim 4, wherein said donor material and said acceptor material have energy level differences in said exciton states substantially equal to a triplet exciton dissociation energy of said donor material.

6. A photovoltaic device according to claim 4, wherein said layer of light responsive material comprises a layer of said acceptor material formed on a layer of said donor material to form a heterojunction photovoltaic cell.

7. A photovoltaic device according to claim 4, wherein said layer of light responsive material comprises said acceptor material and said donor material in a bulk form to form a bulk junction photovoltaic cell.

8. A photovoltaic device according to claim 1, further comprising a hole/exciton blocking layer formed on said layer of light responsive material, wherein said second electrode is formed on said hole/exciton blocking layer.

9. A photovoltaic device according to claim 8, wherein said hole/exciton blocking layer formed on said layer of light responsive material consists essentially of BCP.

10. A photovoltaic device according to claim 1, wherein said second electrode is formed on said layer of light responsive material to be in direct contact with at least a portion of said layer of light responsive material.

11. A photovoltaic device according to claim 4, wherein said acceptor material comprises C₆₀.

12. A photovoltaic device according to claim 11, wherein said donor material comprises PtOEP.

13. A photovoltaic device according to claim 12, further comprising a hole/exciton blocking layer formed on said layer of light responsive material, wherein said second electrode is formed on said hole/exciton blocking layer, and wherein said hole/exciton blocking layer consists essentially of BCP.

14. A photovoltaic device according to claim 1, wherein said first electrode is formed on a substrate that is substantially transparent to electromagnetic radiation over a range of wavelengths that include wavelengths corresponding to wavelengths suitable to excite said triplet exciton state.

15. A photovoltaic device according to claim 14, wherein said first electrode comprises a layer of ITO formed on said substrate and a layer of PEDOT formed on said layer of ITO.

16. A photovoltaic device according to claim 7, wherein said layer of light responsive material comprises a polymer blend of P3HT and PCBM, said P3HT comprising heavy metal nanoparticles.

17. A method of generating electric power, comprising:
illuminating a layer of light responsive material with electromagnetic radiation to cause triplet excitons to form in said layer of light responsive material;
allowing said excitons to migrate to an interface region of said donor and acceptor materials to dissociate electrons from corresponding holes of said excitons; and
collecting at least some of said dissociated electrons at an electrode to be available for providing electrical power.

18. A method of producing a photovoltaic device, comprising:
providing a substrate;
forming a first electrode on said substrate;
selecting a light responsive material that comprises a triplet material having a relatively stable triplet exciton state,
forming a layer of said light responsive material on said first electrode; and
forming a second electrode in electrically conducting contact with said layer of light responsive material,
wherein said triplet material has a triplet exciton state suitable to be excited by incident electromagnetic radiation to produce electrical power.
